(19) United States
(12) Patent Application Publication
(10) Pub. No.: US 2026/0136838 A1
(43) Pub. Date: May 14, 2026

(54) PIEZOELECTRIC LAMINATED STRUCTURE AND MANUFACTURING METHOD THEREFOR

(71) Applicant: HEFEI NAVIGATION MICROSYSTEM INTEGRATION CO., LTD., Anhui (CN)

(72) Inventors: Dongdong GONG, Anhui (CN); Guoqian WANG, Anhui (CN); Tongzhou ZHAN, Anhui (CN); Yanli SHI, Anhui (CN)

(73) Assignee: HEFEI NAVIGATION MICROSYSTEM INTEGRATION CO., LTD., Anhui (CN)

(21) Appl. No.: 19/178,876

(22) Filed: Apr. 15, 2025

Related U.S. Application Data
(63) Continuation of application No. PCT/CN2024/089386, filed on Apr. 23, 2024.

(30) Foreign Application Priority Data
Apr. 22, 2024 (CN) 202410481187.5

(51) Int. Cl. H10N 30/00; C23C 14/58; C23C 16/34; C23C 16/40; C23C 16/50; C23C 16/52; C23C 28/00; H10N 30/04; H10N 30/05; H10N 30/072; H10N 30/076; H10N 30/082; H10N 30/50; H10N 30/853; H10N 30/87

(52) U.S. Cl. CPC H10N 30/708; C23C 14/5873; C23C 16/345; C23C 16/401; C23C 16/50; C23C 16/52; C23C 28/32; H10N 30/04; H10N 30/05; H10N 30/072; H10N 30/076; H10N 30/082; H10N 30/50; H10N 30/8554; H10N 30/872; H10N 30/878

(57) ABSTRACT

Disclosed are a piezoelectric laminated structure and a manufacturing method therefor. The piezoelectric laminated structure includes a substrate, further including a deflection limiting layer, a piezoelectric layer and a structural layer, where the piezoelectric layer bends and deforms toward the substrate, and the structural layer bends and deforms toward the piezoelectric layer. The method includes: growing a deflection limiting layer on a substrate; sputter-growing a piezoelectric layer, where the piezoelectric layer bends and deforms toward the substrate, and the front face of the substrate deforms and bends toward a back face thereof. The structural layer is deposited on a PZT upper electrode, and the structural layer deforms and bends toward the piezoelectric layer. The structural layer and the substrate are patterned, to form a desired piezoelectric laminated structure. A residual stress and a vibrational stress in an effective working zone are superimposed, which improves device performance.

### CROSS-REFERENCE TO RELATED APPLICATION

This application is a continuation of international application of PCT application serial no. PCT/CN2024/089386, filed on Apr. 23, 2024, which claims the priority benefit of China application no. 202410481187.5, filed on Apr. 22, 2024. The entirety of each of the above-mentioned patent applications are hereby incorporated by reference herein and made a part of this specification.

### TECHNICAL FIELD

The present disclosure relates to the technical field of piezoelectric laminated structures and manufacturing in semiconductor processes, and in particular to a piezoelectric laminated structure and a manufacturing method therefor.

### BACKGROUND

At present, a piezoelectric laminated structure, as a core component of a piezoelectric MEMS sensor, usually exhibits residual stresses caused by differences in thermal expansion coefficients of various material layers. These residual stresses induced by high-temperature processes will make the piezoelectric laminated structure deform and bend in a certain direction. After bending deformation of the piezoelectric laminated structure occurs, a cross-section of the laminated structure is displaced, and a displacement of the cross-section perpendicular to an axial direction of the laminated structure is called deflection, as shown in FIG. 1.

Generally, the piezoelectric MEMS sensor is designed and processed to have a sufficiently flat piezoelectric laminated structure with an extremely low positive or negative deflection. However, due to the differences in thermal expansion coefficients of the laminated structure, the laminated structure certainly has a certain deflection. The deflection of the piezoelectric laminated structure is generally undesirable for most MEMS devices. However, the deflection of the laminated structure is utilized for piezoelectric MEMS sensors for vibration detection, such as microphones, ultrasonic sensors, acoustic vibration sensors and the like. As shown in FIG. 2, the deflection caused by a residual stress Se is parabolic, and the deflection caused by a stress Sb generated by vibration on the laminated structure is approximately linear. Therefore, a combined stress S after superposition amplifies on a negative deflection side where Se and Sb are superposed, and diminishes on a positive deflection side where Se and Sb offset each other. Therefore, in technical applications, a final deflection of the piezoelectric laminated structure is preferably in an interval where a combined stress formed by superimposing residual and vibrational stresses amplifies.

In the piezoelectric laminated structure, a structural layer is usually thicker than a piezoelectric layer for several to dozens of times, and therefore a neutral plane of the piezoelectric laminated structure is located in the structural layer. An actuation mechanism of piezoelectric vibration indicates that an area from the neutral planes to the piezoelectric layer is an effective working zone of the piezoelectric laminated structure. In practical applications, the piezoelectric laminated structure has an initial deflection, and different deflections exert different effects on the piezoelectric laminated structure. When a deflection is oriented toward the piezoelectric layer, that is, when one side of the piezoelectric layer protrudes outward, a residual stress and a vibrational stress in an area from the neutral plane to the piezoelectric layer are superimposed, while stresses in an area from the neutral plane to the structural layer offset each other. In this case, superposition of stresses in the effective working zone of the piezoelectric laminated structure enhances sensitivity of a diaphragm, which is beneficial to improving device performance. When a deflection of the piezoelectric laminated structure is oriented toward the structural layer, that is, when one side of the structural layer protrudes outward, the stress situation is reversed, which exerts adverse effects on device performance.

Among various piezoelectric materials, a lead zirconate titanate (PZT) piezoelectric material is used to grow a PZT piezoelectric film on a substrate through a magnetron sputtering deposition process, and the film features high quality, a high piezoelectric coefficient, high stability and reliability. However, a substantial residual stress is generated during growth of a PZT piezoelectric film. This residual stress is a tensile stress and is much larger than an initial deflection of the substrate. For a conventional substrate based on a silicon wafer or silicon-on-insulator (SOI) wafer, the laminated structure exhibits a large negative deflection after growth of a PZT film layer (the piezoelectric layer), that is, the deflection of the piezoelectric laminated structure is oriented towards the structural layer (as shown in FIG. 3A). Therefore, a piezoelectric laminated structure with the deflection oriented toward the piezoelectric layer is hardly obtained through traditional techniques.

To sum up, the present disclosure provides a piezoelectric laminated structure and a manufacturing method therefor to solve the problems mentioned above.

### SUMMARY

In order to solve problems mentioned in the Background, an objective of the present disclosure is to provide a piezoelectric laminated structure and a manufacturing method, with an aim to improve device performance in a way that a structural layer grown on a surface of a piezoelectric layer bends and deforms toward the piezoelectric layer due to a negative deflection induced by a residual stress of the piezoelectric layer, and a residual stress and a vibrational stress in an effective working zone are superimposed due to a negative deflection of the piezoelectric laminated structure.

In an example of the present disclosure, a piezoelectric laminated structure and a manufacturing method therefor are provided.

In a first aspect: A piezoelectric laminated structure includes a substrate, where the substrate is provided with a front face and a back face opposite to each other, and further includes a deflection limiting layer, a piezoelectric layer and a structural layer that are sequentially arranged on the front face of the substrate in a laminated manner, where the piezoelectric layer bends and deforms toward the substrate, and the structural layer bends and deforms toward the piezoelectric layer, such that an initial deflection of the piezoelectric laminated structure is negative, and a residual stress and a vibrational stress in an effective working zone of the piezoelectric laminated structure are superimposed.

As a further solution of the present disclosure, a back cavity is formed on the back face of the substrate.

As a further solution of the present disclosure, the substrate is a silicon wafer substrate.

As a further solution of the present disclosure, the piezoelectric layer includes a PZT lower electrode, a PZT film and a PZT upper electrode that are sequentially arranged in a laminated manner, where a deflection of the PZT film is negative.

As a further solution of the present disclosure, a thickness of the PZT film is 0.1-5 um.

As a further solution of the present disclosure, the structural layer is thicker than the PZT film.

As a further solution of the present disclosure, a metal layer that facilitates electrode leading-out is grown on a surface of either of the PZT lower electrode and the PZT upper electrode.

As a further solution of the present disclosure, a longitudinal projection area of the PZT upper electrode is smaller than a longitudinal projection area of the PZT film, and the structural layer is arranged on the surface of the PZT upper electrode and extends to the surface of the PZT film.

As a further solution of the present disclosure, the deflection limiting layer is made of silicon oxide, and a thickness of the deflection limiting layer is 10-500 nm.

As a further solution of the present disclosure, the structural layer is made of silicon oxide and/or silicon nitride, and the thickness of the structural layer is 0.5-25 um.

As a further solution of the present disclosure, the structural layer is a double-layer structure or a triple-layer structure in which silicon oxide and silicon nitride are alternately laminated sequentially.

In a second aspect: A manufacturing method for the piezoelectric laminated structure, includes the following steps:
S1, growing a deflection limiting layer on a front face of a substrate through a thermal oxidation process;
S2, sputter-growing a piezoelectric layer on the deflection limiting layer, where the piezoelectric layer bends and deforms toward the substrate due to its intrinsic stress;
S3, patterning the piezoelectric layer;
S4, growing a structural layer on the patterned piezoelectric layer, where the structural layer bends and deforms toward the piezoelectric layer;
S5, patterning the structural layer;
S6, etching a back face of the substrate to form a back cavity;
where the piezoelectric layer bends and deforms toward the substrate, and the structural layer bends and deforms toward the piezoelectric layer, such that an initial deflection of the piezoelectric laminated structure is negative, and a residual stress and a vibrational stress in an effective working zone of the piezoelectric laminated structure are superimposed.

As a further solution of the manufacturing method of the present disclosure, the sputter-growing a piezoelectric layer on the deflection limiting layer in the S2 includes:
S21, sputter-growing a PZT lower electrode on the deflection limiting layer;
S22, sputter-growing a PZT film on the PZT lower electrode, where the PZT film bends and deforms toward the PZT lower electrode due to its intrinsic stress; and
S23, sputter-growing a PZT upper electrode on the PZT film, where the PZT upper electrode bends and deforms in a bending direction of the PZT film.

As a further solution of the manufacturing method of the present disclosure, the patterning the piezoelectric layer in the S3 includes:
S31, etching the PZT upper electrode through ion beam etching (IBE) to pattern the PZT upper electrode;
S32, wet-etching the PZT film to expose a portion of the PZT lower electrode; and
S33, etching the PZT lower electrode through IBE to pattern the PZT lower electrode, so as to complete patterning of the piezoelectric layer.

As a further solution of the manufacturing method of the present disclosure, the following steps are further included:
S34, growing a metal layer on a surface of the piezoelectric layer, where the metal layer covers exposed areas of the piezoelectric layer and the deflection limiting layer; and
S35, patterning the metal layer, and retaining portions of the metal layer on surfaces of the PZT lower electrode and the PZT upper electrode.

As a further solution of the manufacturing method of the present disclosure, the structural layer is generated based on a low-temperature plasma-enhanced chemical vapor deposition (PECVD) process, and the structural layer is a double-layer structure or a triple-layer structure in which silicon oxide and silicon nitride are alternately laminated sequentially.

As a further solution of the manufacturing method of the present disclosure, a stress direction and magnitude of the structural layer are controlled by adjusting parameters of the low-temperature PECVD process, including temperature, time, power and chamber pressure.

The present disclosure has the following beneficial effects:

1. In the present disclosure, the structural layer is arranged on the piezoelectric layer through the PECVD process, the piezoelectric layer deforms and bends downward due to its intrinsic stress, and the stress direction and magnitude of the structural layer are controlled by adjusting parameters of the PECVD process, which achieves the purpose of deformation and deflection of the structural layer toward the piezoelectric layer. A structural deflection of each layer from a neutral plane of the laminated structure to the piezoelectric layer in the present disclosure is negative, a residual stress and a vibrational stress in an effective working zone of the piezoelectric laminated structure are superimposed, and a vibration amplitude of a diaphragm is amplified, which enhances detection sensitivity and improves device performance.

2. The structural layer of the present disclosure includes three layers, i.e., a middle layer, a bottom layer and a top layer, where the middle layer mainly controls the neutral plane, the bottom layer mainly enhances adhesion of the middle layer and improves film quality, and the top layer mainly increases tensile strength of the middle layer and improves stability of the entire structural layer. The triple-layer structure ensures structural stability, reliability, and a higher yield rate.

### BRIEF DESCRIPTION OF THE DRAWINGS

FIG. 1 is a schematic diagram illustrating deflection generation in a piezoelectric laminated structure.

FIG. 2 is a schematic diagram of curves of residual stresses, vibrational stresses, and combined stresses of a piezoelectric laminated structure.

FIG. 3A and FIG. 3B are schematic diagrams of a piezoelectric laminated structure that protrudes toward a structural layer and a piezoelectric laminated structure that protrudes toward a piezoelectric layer.

FIG. 4 is a schematic diagram of a piezoelectric laminated structure of the present disclosure.

FIG. 5 is an exploded view of a piezoelectric laminated structure of the present disclosure.

FIG. 6 is a structural schematic diagram of FIG. 5 in an example.

FIG. 7 is a sectional view of FIG. 5 of the present disclosure.

FIG. 8 is a sectional view of FIG. 6 of the present disclosure.

FIG. 9 is a schematic diagram of a structural layer in a preferred solution of the present disclosure.

FIGS. 10-12 are schematic diagrams of structural layers in various examples of the present disclosure.

FIGS. 13-18 are schematic diagrams of a process flow of FIG. 5.

FIGS. 19-22 are schematic diagrams of a partial process flow of FIG. 6.

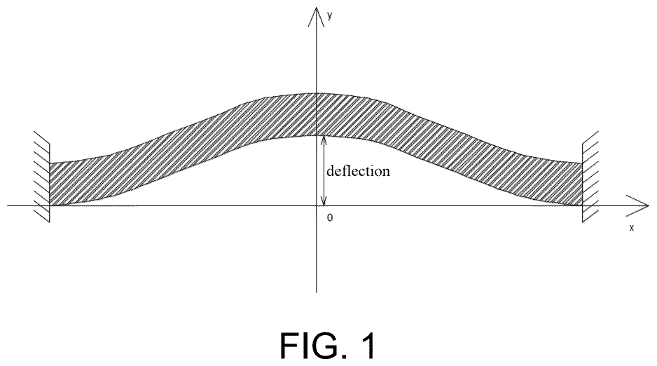

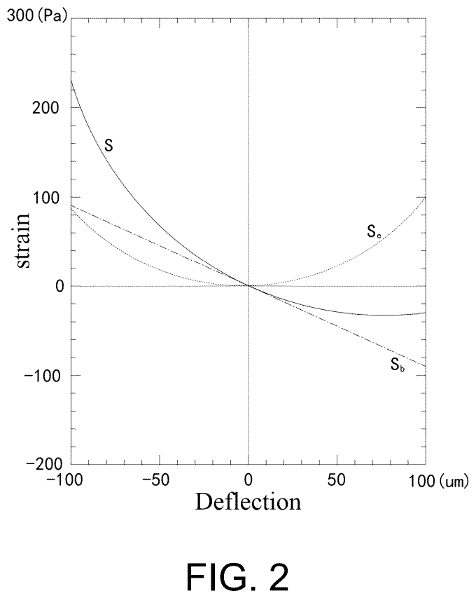

### DESCRIPTION OF THE EMBODIMENTS

Examples of the present disclosure are described in detail below, and examples of the examples are shown in accompanying drawings, throughout which identical or similar reference numerals denote identical or similar elements or elements having identical or similar functions. The examples described with reference to the accompanying drawings are exemplary and only intended to explain the present disclosure, instead of being construed as limiting the present disclosure.

To make the objectives, technical solutions and advantages of the present disclosure clearer, the present disclosure will be described in further detail below in conjunction with specific examples.

### Example 1

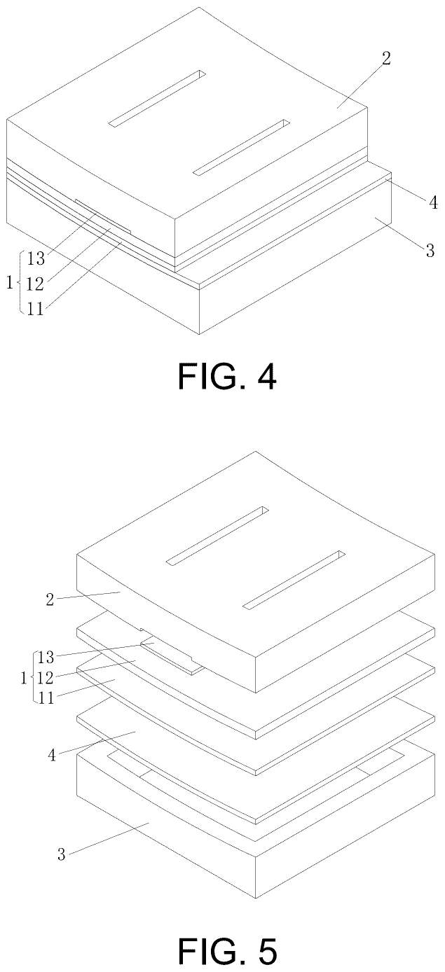

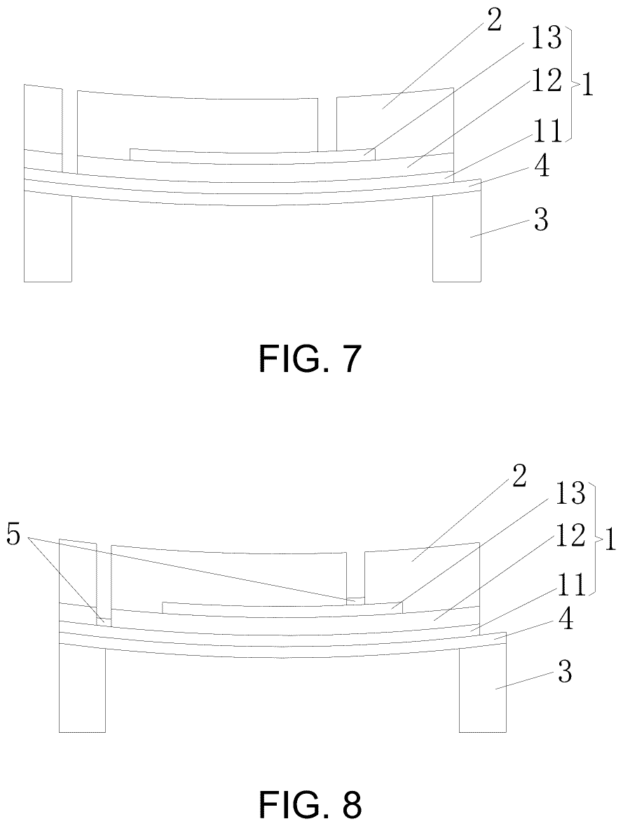

As illustrated in FIGS. 4, 5 and 7, a piezoelectric laminated structure provided in an example of the present disclosure includes a substrate 3, a deflection limiting layer 4, a piezoelectric layer 1 and a structural layer 2 that are sequentially arranged in a laminated manner, where a back cavity is formed at a bottom of the substrate 3, and a diaphragm is formed in an area composed of the deflection limiting layer 4 on a longitudinal projection area of the back cavity, the piezoelectric layer 1 and the structural layer 2.

The piezoelectric layer 1 in an example of the present disclosure deforms and bends downward due to stress after growth, and the structural layer 2 is formed on a surface of the piezoelectric layer 1 through a plasma-enhanced chemical vapor deposition (PECVD) process. A stress direction and magnitude of the structural layer 2 are controlled by adjusting parameters of the PECVD process, which causes deformation and bending of the structural layer 2 toward the piezoelectric layer 1. A structural deflection of each layer from a neutral plane to the piezoelectric layer is negative, and a residual stress and a vibrational stress in an effective working zone of the piezoelectric laminated structure are superimposed, which enhances detection sensitivity and improves device performance.

Optionally, the substrate 3 is a silicon wafer, and the silicon wafer exhibits a near-zero deflection, thereby minimizing an impact of the substrate 3 on the deflection of each layer during manufacturing.

As illustrated in FIGS. 4 and 5, the deflection limiting layer 4 may be grown on a front face of the silicon wafer through a thermal oxidation process to form the deflection limiting layer 4; and a stress of silicon oxide grown by thermal oxidation causes the deflection limiting layer 4 to induce a negative deflection, but the deflection limiting layer 4 is much thinner than the substrate 3, such that the deflection limiting layer 4 has no effect on the deflection of the entire laminated structure. Additionally, the silicon oxide grown by thermal oxidation has a higher density and a higher Young's modulus, and due to an interfacial effect, the deflection limiting layer 4 limits an excessive deflection of the piezoelectric layer 1 during growth, thereby avoiding adverse effects. Optionally, a thickness of the deflection limiting layer 4 is 10-500 nm.

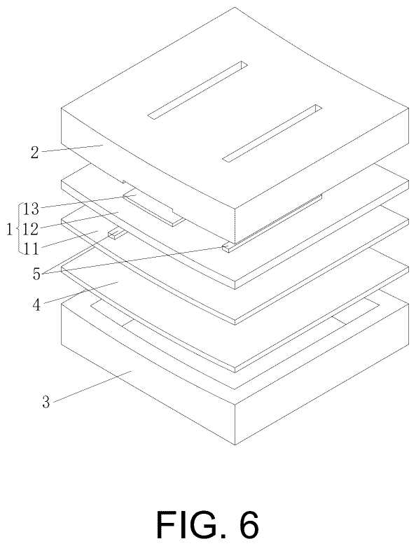

As illustrated in FIGS. 6, 7 and 8, the piezoelectric layer 1 is formed on a surface of the deflection limiting layer 4, and the piezoelectric layer 1 includes a PZT lower electrode 11, a PZT film 12 and a PZT upper electrode 13 that are arranged in a laminated manner, where the PZT film 12 exhibits a negative deflection.

Optionally, the PZT upper electrode 13 and the PZT lower electrode 11 are buffer layers formed by Pt, Au, Ti, and other metals and metal compounds; and optionally, a thickness of the PZT film 12 is 0.1-5 um.

Due to an effect of the deflection limiting layer 4, the deflection of the PZT film 12 is affected by the thickness of the PZT film 12, that is, variations in the thickness of the PZT films 12 cause differences in the deflection of the piezoelectric laminated structure. A large tensile stress of the PZT film 12 is induced during growth of the PZT film 12, and therefore the PZT film 12 always exhibits a negative deflection after complete growth, such that the entire piezoelectric laminated structure bends downward. The deflection limiting layer 4, in combination with control of growth process parameters of the PZT film 12, ensures that the deflection of the PZT film 12 is controlled in an appropriate range, which avoids reliability problems of the PZT film 12 such as localized stress concentration, abnormal electric domain distribution, mechanical fatigue, and material nonlinearity; and moreover, and an excessive deflection of the PZT film 12 is avoided. The excessive deflection affects growth of the structural layer 2 formed through the low-temperature PECVD process, causes risks such as mechanical and electrical nonlinearity, and reduces a linear operating range of the PZT film.

Optionally, a longitudinal projection area of the PZT upper electrode 13 is smaller than a longitudinal projection area of the PZT film 12, and the structural layer 2 is arranged on a surface of the PZT upper electrode 13 and extends to a surface of the PZT film 12.

Optionally, the structural layer 2 is made of silicon oxide and/or silicon nitride.

Optionally, the structural layer 2 is a double-layer structure in which silicon oxide and silicon nitride are laminated sequentially, and as illustrated in FIG. 9, silicon oxide is much thicker than silicon nitride.

Optionally, the structural layer 2 is a double-layer structure in which silicon oxide and silicon nitride are laminated sequentially, and as illustrated in FIG. 10, silicon nitride is much thicker than silicon oxide.

Optionally, the structural layer 2 is a triple-layer structure in which silicon nitride, silicon oxide and silicon nitride are laminated sequentially, and as illustrated in FIG. 11, silicon oxide is much thicker than silicon nitride.

Optionally, the structural layer 2 is a triple-layer structure in which silicon oxide, silicon nitride and silicon oxide are laminated sequentially, and as illustrated in FIG. 12, silicon nitride is much thicker than silicon oxide.

Silicon nitride and silicon oxide are significantly different in the Young's modulus, and stresses of silicon nitride and silicon oxide also vary greatly under the PECVD process. Therefore, a triple-layer structure and process conditions of the structural layer 2 is used to adjust the deflection of the PZT film 12. In the triple-layer structure, a main structure of the structural layer 2 is a middle layer, and performance of the device is mainly determined by a material and thickness of the middle layer. A bottom layer mainly enhances adhesion of the middle layer and improves film quality, and a top layer mainly increases tensile strength of the middle layer and improves stability of the structural layer 2. The triple-layer structure ensures structural stability, reliability, and a higher yield rate.

Optionally, a thickness of the structural layer 2 is 0.5-25 um, and the structural layer 2 is thicker than the PZT film 12. Optionally, the structural layer 2 is deposited on the surface of the piezoelectric layer 1 through the low-temperature PECVD process.

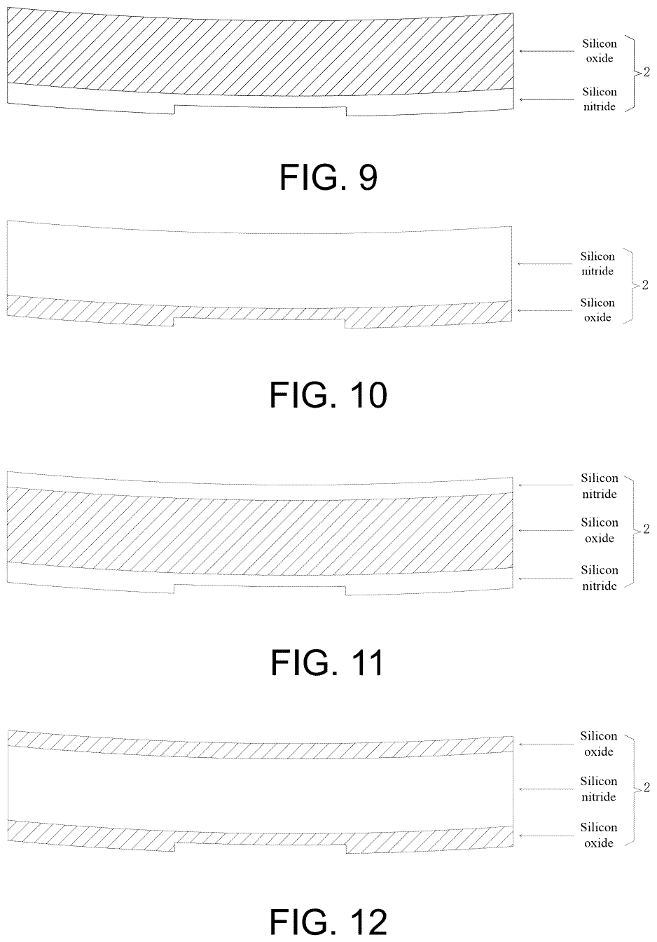

Optionally, as illustrated in FIGS. 6 and 8, a metal layer 5 is arranged on a surface of the PZT lower electrode 11 and the surface of the PZT upper electrode 13 respectively, and the structural layer 2 and the PZT film 12 are provided with grooves in a penetrated manner to expose the metal layers 5. The metal layer 5 is made of aluminum, gold or any other pure metal, or an alloy or compound such as an aluminum-copper alloy.

### Example 2

A preparation method provided in an example of the present disclosure includes the following steps:

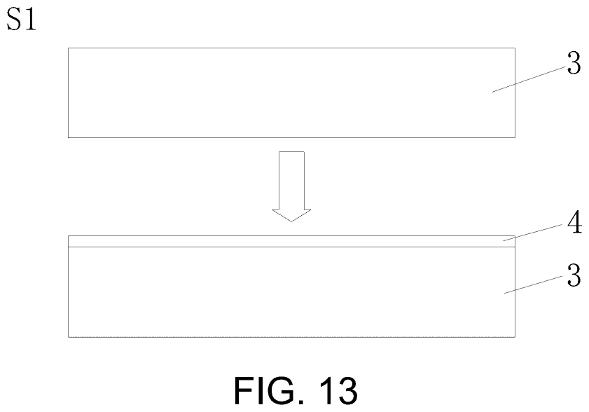

With reference to FIG. 13, S1, prepare a substrate 3, where the substrate 3 is provided with a front face and a back face opposite to each other, and form a deflection limiting layer 4 on a front face of the substrate 3 through a thermal oxidation process, to control a position of a neutral plane and limit a deflection of a piezoelectric layer 1. The substrate 3 is a low-deflection silicon wafer; and the deflection limiting layer 4 is made of silicon oxide with a thickness of 10-500 nm, and the deflection limiting layer 4 is grown on the front face of the substrate 3 through the thermal oxidation process.

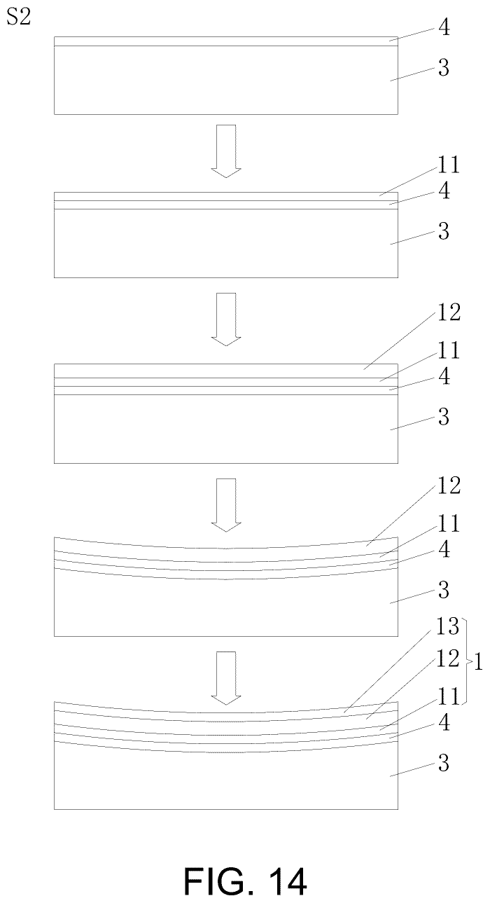

With reference to FIG. 14, S2, sputter-grow a piezoelectric layer 1 on a surface of the deflection limiting layer 4. The piezoelectric layer 1 includes a PZT lower electrode 11, a PZT film 12 and a PZT upper electrode 13, and a growth sequence is as follows: the PZT lower electrode 11 is sputter-grown on the deflection limiting layer 4; the PZT film 12 is sputter-grown on the PZT lower electrode 11; and the PZT upper electrode 13 is sputter-grown on the PZT film 12.

A thickness of the PZT film 12 is 0.1-5 um. Before growth of the PZT film 12, the substrate 3, the deflection limiting layer 4 and the PZT lower electrode 11 of a laminated structure are all in a flat state, and after the growth of the PZT film 12, the entire laminated structure deforms bends downward due to stress, with a concave curvature formed.

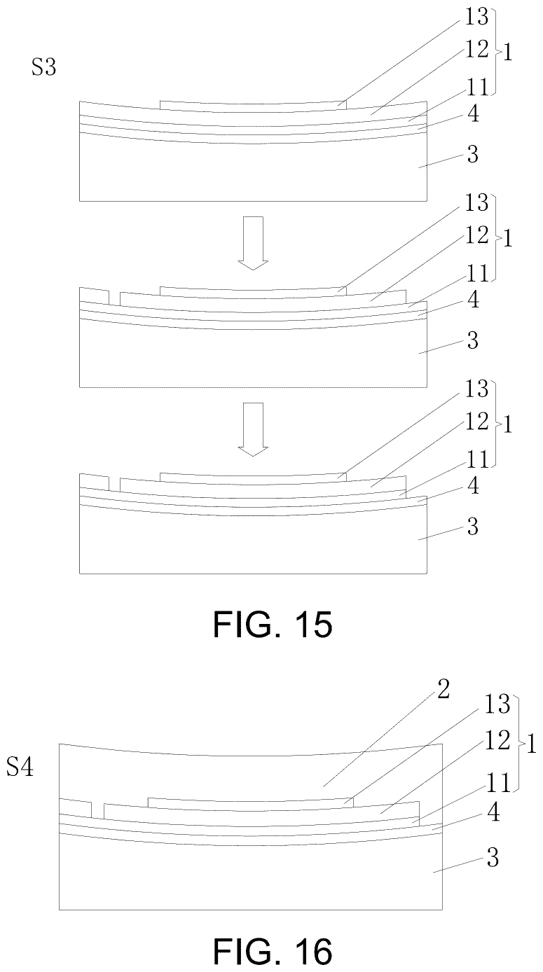

With reference to FIG. 15, S3, the PZT upper electrode 13, the PZT film 12 and the PZT lower electrode 11 are patterned sequentially, with a process as follows:
S31, etch the PZT upper electrode 13 through ion beam etching (IBE) to pattern the PZT upper electrode 13.
S32, wet-etch the PZT film 12 to expose a portion of the PZT lower electrode 11.
S33, etch the PZT lower electrode 11 through IBE to pattern the PZT lower electrode 11, so as to complete patterning of the piezoelectric layer 1.

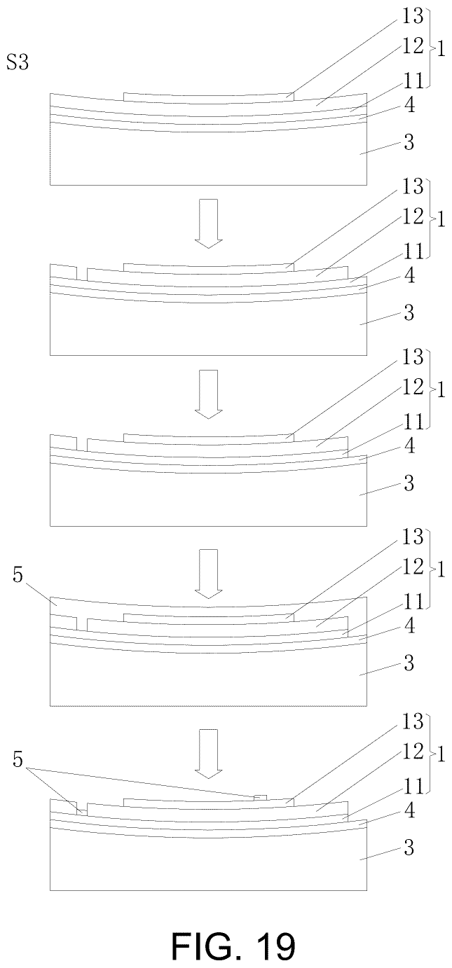

Optionally, with reference to FIG. 19, the following process steps are further included:
S34, grow a metal layer 5 on a surface of the piezoelectric layer 1, where the metal layer 5 covers exposed areas of the piezoelectric layer 1 and the deflection limiting layer 4; and
S35, pattern the metal layer 5, and retain portions of the metal layer 5 on surfaces of the PZT film 12 and the PZT upper electrode 13.

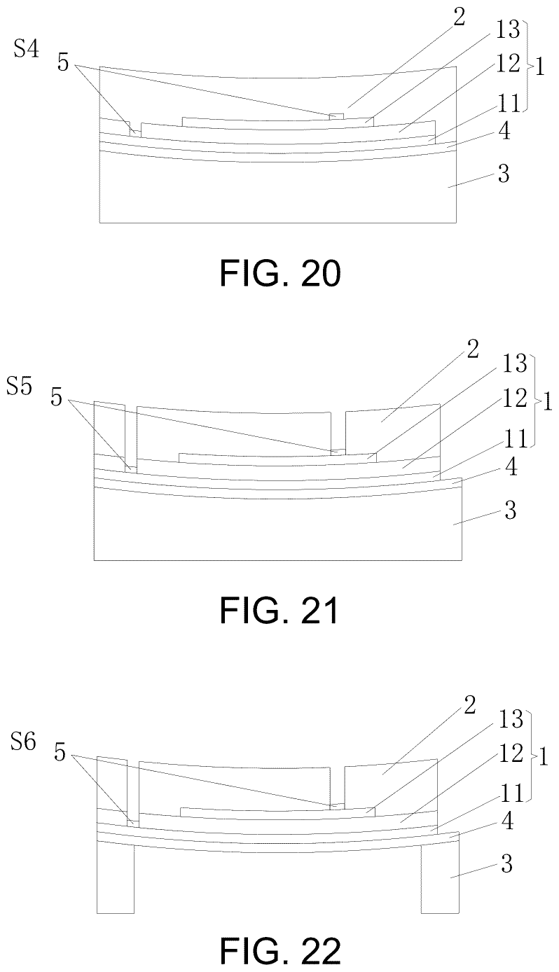

With reference to FIGS. 16 and 20, S4, grow a structural layer 2 on the surface of the piezoelectric layer 1. The structural layer 2 is deposited on surfaces of the PZT upper electrode 13 and the PZT film 12 through the low-temperature PECVD process. After the structural layer 2 is deposited, the structural layer 2 deforms toward the PZT film 12 to obtain a desired deflection of the piezoelectric laminated structure and improve performance of the piezoelectric laminated structure. The low-temperature PECVD process is executed at a temperature below 290° C.

A thickness of the structural layer 2 is 0.5-25 um, and the structural layer 2 is made of silicon oxide and/or silicon nitride, where silicon oxide is represented as SiO₂, and silicon nitride is represented as Si₃N₄. Silicon nitride and silicon oxide are grown through the PECVD process. A stress direction and magnitude of the structural layer are controlled by adjusting parameters of the low-temperature PECVD process, including temperature, time, power and chamber pressure. The stress is controlled more accurately.

Optionally, the structural layer 2 is a double-layer structure in which silicon oxide and silicon nitride are laminated sequentially. Conditions of the low-temperature PECVD process remain unchanged, and the double-layer structure in which silicon oxide and silicon nitride are laminated sequentially is adopted. When silicon nitride is much thicker than silicon oxide, the thickness of the structural layer 2 is changed. A deflection of the piezoelectric laminated structure 5 is measured, as illustrated in Table 1:

TABLE 1
Deflection measurement of a Si₃N₄—SiO₂ structural
layer and the piezoelectric laminated structure

| | Deflection | | | | Piezoelectric |
|---|---|---|---|---|---|
| | control | | | | laminated |
| Substrate | layer | PZT film | SiO₂ | Si₃N₄ | structure |
| thick- | thick- | thick- | thick- | thick- | deflec- |
| ness, μm | ness, nm | ness, μm | ness, nm | ness, μm | tion, μm |
| 400 | 50 | 0.5 | 25 | 1 | −17.48 |
| | | | | 5 | −0.01 |
| | | 1 | | 2 | −63.41 |
| | | | | 5 | −53.26 |
| | | | | 10 | −3.33 |
| | | 2 | | 3 | −126.58 |
| | | | | 5 | −112.9 |
| | | | | 10 | −103.71 |

Deflection measurement results in Table 1 show the impact of thickness change of the structural layer 2 on the deflection of the piezoelectric laminated structure when the piezoelectric layer 1 varies in thickness.

Optionally, the structural layer 2 is a double-layer structure in which silicon oxide and silicon nitride are laminated sequentially. Conditions of the low-temperature PECVD process remain unchanged. When the double-layer structure in which silicon oxide and silicon nitride are laminated sequentially is adopted, and when silicon oxide is much thicker than silicon nitride, the thickness of the structural layer 2 is changed. A deflection of the piezoelectric laminated structure is measured, as illustrated in Table 2:

TABLE 2
Deflection measurement of a SiO₂—Si₃N₄ structural
layer and the piezoelectric laminated structure

| | Deflection | | | | Piezoelectric |
|---|---|---|---|---|---|
| | control | | | | laminated |
| Substrate | layer | PZT film | Si₃N₄ | SiO₂ | structure |
| thick- | thick- | thick- | thick- | thick- | deflec- |
| ness, μm | ness, nm | ness, μm | ness, nm | ness, μm | tion, μm |
| 400 | 50 | 0.5 | 25 | 2 | 26.49 |
| | | 1 | | 5 | 6.42 |
| | | | | 10 | 43.17 |
| | | 2 | | 3 | −106.7 |
| | | | | 5 | −62.92 |
| | | | | 10 | −40.16 |

Deflection measurement results in Table 2 show the impact of thickness change of the structural layer 2 on the deflection of the piezoelectric laminated structure when the piezoelectric layer 1 varies in thickness.

Optionally, the structural layer 2 is a triple-layer structure in which silicon oxide, silicon nitride and silicon oxide are laminated sequentially. Conditions of the low-temperature PECVD process remain unchanged. When the triple-layer structure in which silicon oxide, silicon nitride and silicon oxide are laminated sequentially is adopted, and when silicon nitride is much thicker than silicon oxide, the thickness of the structural layer 2 is changed. A deflection of the piezoelectric laminated structure is measured, as illustrated in Table 3:

TABLE 3
Deflection measurement of a SiO₂—Si₃N₄—SiO₂ structural
layer and the piezoelectric laminated structure

| Substrate | Deflection | PZT film | SiO₂ | Si₃N₄ | SiO₂ | Piezoelectric |
|---|---|---|---|---|---|---|
| thickness, | control layer | thickness, | thickness, | thickness, | thickness, | laminated structure |
| μm | thickness, nm | μm | nm | μm | nm | deflection, μm |
| 400 | 50 | 1 | 50 | 2 | 50 | −64.03 |
| | | | | 3 | | −32.74 |
| | | | | 5 | | −26.46 |
| | | 2 | | 5 | | −119.19 |
| | | | | 10 | | −55.92 |
| | | | | 20 | | −13.55 |
| | | 5 | | 10 | | −140.98 |
| | | | | 20 | | −115.07 |

Deflection measurement results in Table 3 show the impact of thickness change of the structural layer 2 on the deflection of the piezoelectric laminated structure when the piezoelectric layer 1 varies in thickness.

Optionally, the structural layer 2 is a triple-layer structure in which silicon nitride, silicon oxide and silicon nitride are laminated sequentially. Conditions of the low-temperature PECVD process remain unchanged. When the triple-layer structure in which silicon nitride, silicon oxide and silicon nitride are laminated sequentially is adopted, and when silicon oxide is much thicker than silicon nitride, the thickness of the structural layer 2 is changed. A deflection of the piezoelectric laminated structure is measured, as illustrated in Table 4:

TABLE 4
Deflection measurement of a Si₃N₄—SiO₂—Si₃N₄
structural layer and the piezoelectric laminated structure

| Substrate | Deflection | PZT film | Si₃N₄ | SiO₂ | Si₃N₄ | Piezoelectric |
|---|---|---|---|---|---|---|
| thickness, | control layer | thickness, | thickness, | thickness, | thickness, | laminated structure |
| μm | thickness, nm | μm | nm | μm | nm | deflection, μm |
| 400 | 50 | 1 | 50 | 2 | 50 | −30.8 |
| | | | | 3 | | −20.42 |
| | | | | 5 | | 6.15 |
| | | 2 | | 5 | | −91.64 |
| | | | | 10 | | −35.74 |
| | | | | 20 | | 15.74 |
| | | 5 | | 10 | | −78.69 |
| | | | | 20 | | −22.31 |

Deflection measurement results in Table 4 show the impact of thickness change of the structural layer 2 on the deflection of the piezoelectric laminated structure when the piezoelectric layer 1 varies in thickness.

It is seen from Tables 1-4 that a thicker piezoelectric layer 1 induces a larger negative deflection, and a thicker structural layer 2 induces a larger positive deflection. Therefore, the deflection of the piezoelectric laminated structure is adjusted based on the thickness of the structural layer 2. A final deflection of the piezoelectric laminated structure results from stress superposition of the piezoelectric layer 1 and structural layer 2, and the final deflection is not necessarily negative. Therefore, thicknesses of the piezoelectric layer 1 and the structural layer 2 needs to be reasonably set to ensure a final deflection of the entire piezoelectric laminated structure is negative.

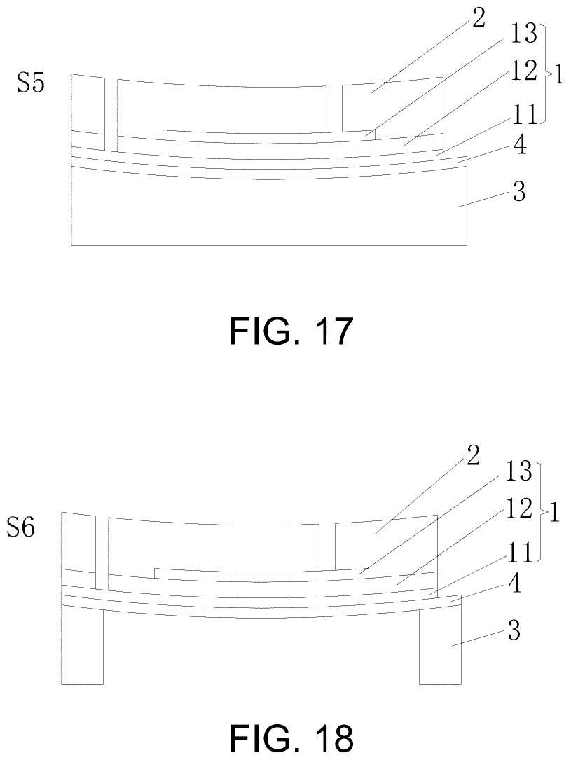

With reference to FIGS. 17 and 21, S5, pattern the structure layer 2 to form a desired piezoelectric laminated structure. The structure layer 2 is etched through ICP to expose portions of the PZT upper electrode 13, the PZT lower electrode 11 and the deflection limiting layer 4.

With reference to FIGS. 18 and 22, S6, pattern the substrate 3 through dry etching or wet etching to expose a back face of the deflection limiting layer 4 and form a back cavity, where the deflection limiting layer 4, the piezoelectric layer 1 and the structural layer 2 corresponding to a projection area of the back cavity jointly form a diaphragm.

Optionally, when the structural layer 2 is patterned, the metal layer 5 is exposed, as illustrated in FIG. 21.

Optionally, in an example of the present disclosure, the front or back face of the laminated structure is sealed to form an air or vacuum cavity of an encapsulation structure, which enables to modulate gas-film damping or mechanical damping, thereby further improving the performance of the device.

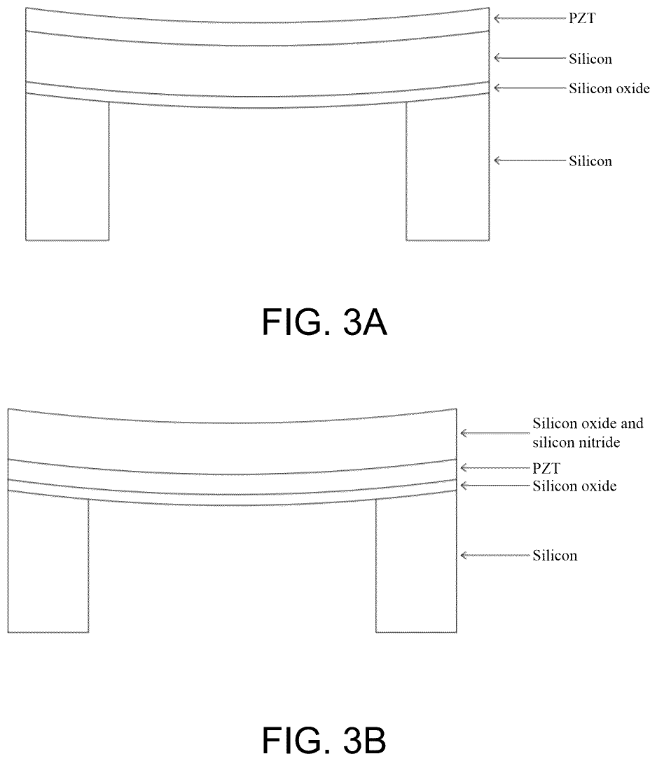

The piezoelectric laminated structure and the manufacturing method therefor provided in the present disclosure are characterized in that the residual stress induced during growth of the PZT film is a tensile stress, and the laminated structure exhibits a large negative deflection. Growth and patterning of the PZT film (the piezoelectric layer) are first completed, and then the structural layer is deposited on the piezoelectric layer through the PECVD process. The stress direction and magnitude of the structural layer are controlled by adjusting parameters of the PECVD process, which achieves the purpose of deformation and deflection of the structural layer toward the piezoelectric layer. The effective working zone from the neutral planes to the piezoelectric layer enables deflection-oriented deformation of the structural layer toward the piezoelectric layer, that is, one side of the piezoelectric layer protrudes outward (as illustrated in FIG. 3B). The problems mentioned above are solved, and a piezoelectric laminated structure that enables to enhance performance of the device is obtained.

The foregoing descriptions are merely preferred specific implementations of the present disclosure, and are not intended to limit the protection scope of the present disclosure. Any equivalent replacements or changes made by a person skilled in the art according to the technical solution of the present disclosure and the inventive concepts thereof within the technical scope disclosed in the present disclosure shall fall within the protection scope of the present disclosure.

What is claimed is:

1. A piezoelectric laminated structure, comprising a substrate, wherein the substrate is provided with a front face and a back face opposite to each other, and further comprising a deflection limiting layer, a piezoelectric layer and a structural layer that are sequentially arranged on the front face of the substrate in a laminated manner, wherein the piezoelectric layer bends and deforms toward the substrate, and the structural layer bends and deforms toward the piezoelectric layer, such that an initial deflection of the piezoelectric laminated structure is negative, and a residual stress and a vibrational stress in an effective working zone of the piezoelectric laminated structure are superimposed.

2. The piezoelectric laminated structure according to claim 1, wherein a back cavity is formed on the back face of the substrate.

3. The piezoelectric laminated structure according to claim 2, wherein the substrate is a silicon wafer substrate.

4. The piezoelectric laminated structure according to claim 3, wherein the piezoelectric layer comprises a PZT lower electrode, a PZT film and a PZT upper electrode that are sequentially arranged in a laminated manner, wherein a deflection of the PZT film is negative.

5. The piezoelectric laminated structure according to claim 4, wherein a thickness of the PZT film is 0.1-5 um.

6. The piezoelectric laminated structure according to claim 4, wherein the structural layer is thicker than the PZT film.

7. The piezoelectric laminated structure according to claim 4, wherein a metal layer that facilitates electrode leading-out is grown on a surface of either of the PZT lower electrode and the PZT upper electrode.

8. The piezoelectric laminated structure according to claim 4, wherein a longitudinal projection area of the PZT upper electrode is smaller than a longitudinal projection area of the PZT film, and the structural layer is arranged on the surface of the PZT upper electrode and extends to a surface of the PZT film.

9. The piezoelectric laminated structure according to claim 1, wherein the deflection limiting layer is made of silicon oxide, and a thickness of the deflection limiting layer is 10-500 nm.

10. The piezoelectric laminated structure according to claim 8, wherein the structural layer is made of silicon oxide and/or silicon nitride, and a thickness of the structural layer is 0.5-25 um.

11. The piezoelectric laminated structure according to claim 10, wherein the structural layer is a double-layer structure or a triple-layer structure in which silicon oxide and silicon nitride are alternately laminated sequentially.

12. A manufacturing method for the piezoelectric laminated structure, used for forming the piezoelectric laminated structure according to claim 1, comprising following steps:
step S1, growing a deflection limiting layer on a front face of a substrate through a thermal oxidation process;
step S2, sputter-growing a piezoelectric layer on the deflection limiting layer, wherein the piezoelectric layer bends and deforms toward the substrate due to its intrinsic stress;
step S3, patterning the piezoelectric layer;
step S4, growing a structural layer on the patterned piezoelectric layer, wherein the structural layer bends and deforms toward the piezoelectric layer;
step S5, patterning the structural layer;
step S6, etching a back face of the substrate to form a back cavity;
wherein the piezoelectric layer bends and deforms toward the substrate, and the structural layer bends and deforms toward the piezoelectric layer, such that an initial deflection of the piezoelectric laminated structure is negative, and a residual stress and a vibrational stress in an effective working zone of the piezoelectric laminated structure are superimposed.

13. The manufacturing method for the piezoelectric laminated structure according to claim 12, wherein the sputter-growing a piezoelectric layer on the deflection limiting layer in the step S2 comprises:
step S21, sputter-growing a PZT lower electrode on the deflection limiting layer;
step S22, sputter-growing a PZT film on the PZT lower electrode, wherein the PZT film bends and deforms toward the PZT lower electrode due to its intrinsic stress; and
step S23, sputter-growing a PZT upper electrode on the PZT film, wherein the PZT upper electrode bends and deforms in a bending direction of the PZT film.

14. The manufacturing method for the piezoelectric laminated structure according to claim 13, wherein the patterning the piezoelectric layer in the step S3 comprises:
step S31, etching the PZT upper electrode through ion beam etching (IBE) to pattern the PZT upper electrode;
step S32, wet-etching the PZT film to expose a portion of the PZT lower electrode; and
step S33, etching the PZT lower electrode through IBE to pattern the PZT lower electrode, so as to complete patterning of the piezoelectric layer.

15. The manufacturing method for the piezoelectric laminated structure according to claim 14, further comprising:
step S34, growing a metal layer on a surface of the piezoelectric layer, wherein the metal layer covers exposed areas of the piezoelectric layer and the deflection limiting layer; and
step S35, patterning the metal layer, and retaining portions of the metal layer on surfaces of the PZT lower electrode and the PZT upper electrode.

16. The manufacturing method for the piezoelectric laminated structure according to claim 12, wherein the structural layer is generated based on a low-temperature plasma-enhanced chemical vapor deposition (PECVD) process, and the structural layer is a double-layer structure or a triple-layer structure in which silicon oxide and silicon nitride are alternately laminated sequentially.

17. The manufacturing method for the piezoelectric laminated structure according to claim 16, wherein a stress direction and magnitude of the structural layer are controlled by adjusting parameters of the low-temperature PECVD process, including temperature, time, power and chamber pressure.
